(19) United States
(12) Patent Application Publication
(10) Pub. No.: US 2010/0140756 A1
(43) Pub. Date: Jun. 10, 2010

(54) APPARATUS FOR MANUFACTURING SILICON OXIDE THIN FILM AND METHOD FOR FORMING THE SILICON OXIDE THIN FILM

(75) Inventors: Kenji Kozasa, Tsukuba-shi (JP); Toshihide Kamata, Tsukuba-shi (JP)

Correspondence Address: VENABLE LLP, P.O. BOX 34385, WASHINGTON, DC, 20043-9998, US

(73) Assignee: National Institute of Advanced Industrial Science and Technology, Tokyo (JP)

(21) Appl. No.: 12/521,253

(22) PCT Filed: Dec. 4, 2007
(86) PCT No.: PCT/JP2007/073400

§ 371 Date: Feb. 26, 2010

(30) Foreign Application Priority Data
Dec. 25, 2006 (JP) 2006-346861

(51) Int. Cl. H01L 29/06; H01L 21/469

(52) U.S. Cl. 257/635; 438/788; 118/724; 438/796; 257/E21.487; 257/E29.005

(57) ABSTRACT

An object of the present invention is to provide a semiconductor thin film device which employs a silicon oxide thin film having an equivalent level of high insulating performance to those currently used in electronic devices, through a low-temperature printing process on a plastic substrate having plasticity or other types of substrates at a temperature equal to or lower than the heat resistant temperature of the substrate, and to provide a method for forming the device. The semiconductor thin film device is formed as follows: a coating film of a silicon compound including a silazane structure or a siloxane structure is formed on a plastic substrate having plasticity; the coating film is converted into a silicon oxide thin film; and the thin film is utilized as part of an insulating layer or a sealing layer.

### TECHNICAL FIELD

The present invention relates to a technique for producing a semiconductor device thin film from a silicon compound thin film applied to a substrate, such as a plastic substrate, having plasticity and a low heat resistant temperature, and to a manufacturing apparatus for implementing the technique.

### BACKGROUND ART

The present invention provides a technique for fabricating a high performance electronic device on a substrate having plasticity, such as a plastic substrate, through a low temperature printing process. A substrate having plasticity is important for producing flexible electronic devices which recently have attracted huge attention in the field of the electronics industry.

Organic polymers exist as thin film materials capable of providing the same function; however, an inorganic oxide film such as a silicon oxide film is suitable in terms of durability against a high electric field and long-term reliability which are important for a device to function as an electronic device.

As for methods for fabricating a silicon oxide thin film through printing, a sol-gel method which employs a metal alkoxide compound as a raw material and a metal organic thermal decomposition method which employs an organometallic compound as a raw material may be used. To complete the reaction for obtaining a silicon oxide thin film through any of these methods, a substrate needs to be baked at a high temperature of 400° C. or more after application of the raw material to a substrate. However, the heat resistant temperatures of currently commonly-used plastic substrates having plasticity are at most 200° C. Accordingly, these methods cannot be used in fabricating electronic devices on such substrates through a printing method.

When silicon oxide is fabricated by subjecting a silicon compound such as a silazane compound to a heating treatment in an oxidative atmosphere at 200° C. or less, the reaction product becomes imperfect, considerably deteriorating the electrical characteristics of the obtained film.

Techniques have already been disclosed in which a silicon oxide thin film is fabricated by subjecting a coating film of a silazane compound to a low temperature heat and moisture treatment with a catalyst, such as an organic amine or palladium, added into the silazane compound (see Patent Documents 1 and 2 given below). However, these techniques have a problem that the catalyst remains in the fabricated silicon oxide thin film and produces the impurity effect which deteriorates electrical characteristics of the silicon oxide thin film.

Meanwhile, a report shows that a reaction at a low temperature is achieved by bringing the above-mentioned catalyst into contact with the raw material from the outside, in place of adding the catalyst into the raw material (see Patent Document 3 given below). However, also in this case, the catalyst component adsorbs onto the surface of the film, which causes the impurity effect described above. In the above-mentioned methods, water molecules adsorbed because of the moisture treatment degrade electrical properties of the film, which necessitates the removal of the water molecules. This removal requires a high-temperature treatment or a heating treatment in a vacuum environment. Accordingly, it is impossible to achieve a low temperature printing process for fabricating a device on a substrate with a low heat resistance, such as a commonly-used plastic substrate with plasticity, as described above.

A technique which aims to solve the above-mentioned problem of the impurities has been known. In the technique, a silicon oxide film is fabricated from a coating film of any of a silazane compound and a siloxane compound which contain no impurities such as a catalyst, through a low temperature treatment at 150° C. or less and ultraviolet light irradiation from an ultraviolet light lamp (see Patent Document 4 given below). However, the resistivity of the silicon oxide insulating films fabricated in this Patent Document is 10¹² to 10¹⁴ Ωcm. Meanwhile, an insulating film usable in a semiconductor device needs to have a resistivity of 10¹⁵ Ωcm which is the same insulating performance as a thermally oxidized film on a surface of crystalline silicon which is a currently commonly-used insulating film element.

Conventionally, a vacuum ultraviolet light CVD apparatus has been known as the above-mentioned semiconductor thin film manufacturing apparatus which utilizes an ultraviolet light lamp (see Patent Document 5 given below). However, this apparatus inevitably requires the substrate to be temporarily introduced into a vacuum treatment chamber in order that, after introduction of a raw material of a thin film in a gas state, an insulating material is formed by conversion from the raw material with ultraviolet light irradiation and deposited and grown on the substrate. Accordingly, it is impossible to take an advantage of the printing process that continuous mass production of thin film devices is possible at a low temperature and at a normal pressure.
Patent Document 1: Japanese Patent Laid-Open No. H6-299118 (1994)
Patent Document 2: Japanese Patent Laid-Open No. H11-105187 (1999)
Patent Document 3: Japanese Patent Laid-Open No. H7-223867 (1995)
Patent Document 4: International Patent Publication No. WO 2006/019157
Patent Document 5: Japanese Patent Laid-Open No. 2003-347296

### DISCLOSURE OF THE INVENTION

### Problems to be Solved by the Invention

The object of the present invention is to provide a semiconductor thin film device which employs a silicon oxide thin film having an equivalent level of high insulating performances to those currently used in electronic devices, through a low temperature printing process on a plastic substrate having plasticity or the like at a temperature equal to or lower than the heat resistant temperature of the substrate, and to provide a method for forming the device.

Furthermore, another object of the present invention is to provide an apparatus for rapidly producing semiconductor thin film devices in large quantities through a simple and low-cost printing method such as a roll-to-roll method by efficiently conducting a method for forming a thin film shown by the present invention.

### Means for Solving the Problems

A semiconductor thin film device is formed by forming a coating film of a silicon compound having a silazane structure or a siloxane structure on a plastic substrate with plasticity, and converting the coating film into a silicon oxide thin film to thereby make the thin film serve as a part of an insulating layer or a sealing layer.

When a silazane compound having a silazane structure is reacted with ozone or atomic oxygen, SiO₂, ammonia, and oxygen are produced according to the following reaction formulas (1) and (2):

2 (—SiH₂—NH—)+2O₃→2(—SiO₂—)+2NH₃+O₂ (1)

(—SiH₂—NH—)+2O→(—SiO₂—)+NH₃ (2).

With this reaction, SiO₂ can be fabricated at a temperature around the room temperature without use of any additives or the like because no particularly high temperature is required to cause this reaction and because this reaction can proceed without using a catalyst. In addition, the substance supplied for this reaction is oxygen, and the substances exhausted after the reaction are ammonia and oxygen. All of these substances are gas, and thus impurities hardly remain in the thin film. Accordingly, a high purity SiO₂ can be fabricated. No water is used in this reaction, and thus deterioration in insulation properties due to residual-adsorbed water can be prevented. In the present invention, the reaction can proceed up to almost complete consumption of Si—N bonds because the reactivity of the reactive ozone or atomic oxygen is considerably high. Accordingly, a high purity SiO₂ thin film can be fabricated.

When a silicon compound having a siloxane structure is reacted with ozone or atomic oxygen, SiO₂, carbon dioxide, and water are produced according to the following reaction formulas (3) and (4):

3(—Si(CH₃)₂—O—)+8O₃→3(—SiO₂—)+6CO₂+9H₂O (3)

(—Si(CH₃)₂—O—)+8O→(—SiO₂—)+2CO₂+3H₂O (4).

As for this reaction, no particularly high temperature is required to cause this reaction, and this reaction can proceed without using a catalyst. Thus, SiO₂ can be fabricated at a temperature around the room temperature without any additives or the like. In the reaction of converting an alkylsiloxane to fabricate SiO₂, carbon dioxide gas and water are generated as the substances exhausted after the reaction. Accordingly, a high purity SiO₂ thin film can be fabricated by performing a heat treatment at 100° C. or higher in combination.

The present invention makes it possible to fabricate a semiconductor device through conversion of a coating film to silicon oxide as follows. A coating film of the silicon compound with a silazane structure or a siloxane structure is formed on a plastic substrate having a heat resistant temperature of 200° C. or less and plasticity, and at least one step of converting the coating film into silicon oxide by irradiating the coating film with ultraviolet light in an atmosphere containing an oxygen chemical species is included in steps of fabricating a silicon oxide insulating film from the coating film. Furthermore, by including at least one step of heating the substrate in an atmospheric gas containing oxygen atoms, such as ozone, oxygen molecules or reactive oxygen atoms, at a temperature equal to or less than the heat resistant temperature of the substrate during or before and after ultraviolet light irradiation onto the silicon oxide in the coating film, the present invention provides a method for manufacturing a semiconductor device with a silicon oxide thin film having an equivalent level of insulating performances and high reliability to those in currently commonly-used thin film transistor semiconductor devices without impairing conventional physical properties of the substrate such as plasticity.

The present invention also provides an apparatus for manufacturing a semiconductor device, the apparatus being used in a method for forming a silicon oxide thin film. The apparatus for manufacturing a semiconductor device includes: a device for applying ultraviolet light onto a substrate having a coating film of the silicon compound with a silazane structure or a siloxane structure in a chamber which is controlled to have an atmospheric gas containing an oxygen chemical species; and a device for heating the substrate.

The present invention further provides a thin film forming apparatus capable of rapidly fabricating, in large quantities, thin films having necessary performances by achieving, at the same time: an arrangement of an ultraviolet light lamp allowing efficient irradiation of light energy from ultraviolet rays necessary for the conversion reaction, onto a thin film applied to a surface of a substrate without adsorption effect of the substrate; and an arrangement of a temperature keeping device allowing efficient transmission of thermal energy to the substrate and the thin film and avoiding inhibition of light irradiation from the ultraviolet light lamp onto the thin film.

The present invention further provides a thin film forming apparatus comprising a temperature keeping device suitable for sufficiently achieving a temperature in the range of 0° C. to 200° C., both inclusive, required temperature to be kept being in the range, and also suitable for eliminating effect on a controlled atmosphere of gas.

The present invention further provides a thin film forming apparatus having an optimum arrangement of an ultraviolet light irradiation device and a temperature keeping device for continuously applying the above-mentioned ultraviolet light and the above-mentioned thermal energy on the thin film applied.

The present invention further provides a thin film forming apparatus capable of controlling the performances and productivity of thin films by introducing, as gases in the controlled atmosphere of gas, a raw material gas which produces ozone or an atomic oxygen species, an inert gas for adjusting the concentration of the raw material gas, and a reactive gas for accelerating the chemical reaction.

The present invention further provides a thin film forming apparatus characterized by being capable of efficiently manufacturing a thin film device on a substrate which is being continuously transferred. To this end, the apparatus includes divided process chambers and a mechanism for continuously transferring the substrate from one of the chambers to another. Each of the following steps is conducted partially or entirely in one of these process chambers by using the mechanism while the substrate is continuously transferred into the process chamber from the other, the steps including: purifying a surface of the substrate; coating the surface of the substrate with a thin film; partially or completely removing components such as a solvent except for raw materials from the coat film; conversion reaction step through ultraviolet light irradiation and a heat treatment; immediately transferring the substrate with the thin film out of the process chamber after completion of the conversion reaction.

The present invention further provides a thin film forming apparatus comprising a gas inlet and a gas outlet as means for keeping the controlled atmosphere of gas in the above-mentioned conversion reaction step. Specifically, the gas inlet introduces a gas having conditions, such as composition, flow rate, pressure and temperature, controlled, and the gas outlet immediately exhausts gas composition after the reaction from a chamber for the conversion reaction step.

The present invention provides a thin film forming apparatus with the following arrangement of the above-mentioned gas inlet and gas outlet for keeping the atmosphere of gas. Specifically, the gas inlet and gas outlet are arranged facing each other in a direction different from a direction in which the substrate is transferred. This arrangement is suitable for keeping the atmosphere of gas efficiently controlled for the coat film without obstruction to other devices in the same process chamber or to means for transferring the substrate.

The present invention further provides a thin film forming apparatus comprising curtain mechanisms at an entrance port for the substrate and an exit port for the substrate of a reaction section, respectively. The curtain mechanisms are provided as physical means for enabling a substrate to be continuously transferred without leak, to the other process chambers or to the outside of the apparatus, of gas in the above-mentioned atmosphere of gas, gas components generated by vaporization or decomposition of components such as a solvent other than the raw materials, and gas components produced in the conversion reaction of the thin film.

The present invention provides a method for continuously forming a semiconductor thin film device on a substrate by using the above-mentioned thin film forming apparatus through a simple and low-cost printing method.

The present invention also provides a semiconductor thin film device having a multi-layer structure which improves the performances of a thin film device formed on a layer of a substance which controls the properties of the surface by forming the layer of a substance on an oxide film generated on a surface of an electrode.

### EFFECT OF INVENTION

A thin film transistor obtained with the manufacturing apparatus and the manufacturing method according to the present invention can be fabricated on a plastic film or the like having a heat resistant temperature of approximately 200° C. and high plasticity through a printing method. This enables continuous film formation at a low-temperature and at a normal pressure which is difficult with a conventional vacuum process. Accordingly, mass production of large-area and flexible devices can be achieved with a simple and low-cost means. Furthermore, in contrast to conventional semiconductor devices formed of a coating film of an organic compound, the device is comprised of a metal oxide which has higher insulating performance, higher withstand voltage and higher reliability, which leads to size reduction, life-lengthening and stability improvement of the device. In addition, the thin film manufactured by the multi-layer structurization according to the present invention enables fabrication of a high quality thin film device, regardless of the properties of a substrate and the surface of an electrode.

### BRIEF DESCRIPTION OF THE DRAWINGS

FIG. 1 is a conceptual view of an apparatus for forming a thin film according to the present invention.

FIG. 2 is an infrared absorption spectrum chart of an insulating film fabricated in Example 1 of the present invention.

FIG. 3 is a chart showing resistivity-electric field strength characteristics of a silicon oxide thin film fabricated in Example 1 of the present invention.

FIG. 4 is a chart showing resistivity-electric field strength characteristics of a silicon oxide thin film fabricated in Example 2 of the present invention.

FIG. 5 is a chart showing resistivity-electric field strength characteristics of a silicon oxide thin film fabricated in Example 3 of the present invention.

FIG. 6 is a chart showing resistivity-electric field strength characteristics of a silicon oxide thin film fabricated in Reference Example 1 of the present invention.

FIG. 7 is a chart showing resistivity-electric field strength characteristics of a silicon oxide thin film fabricated in Reference Example 2 of the present invention.

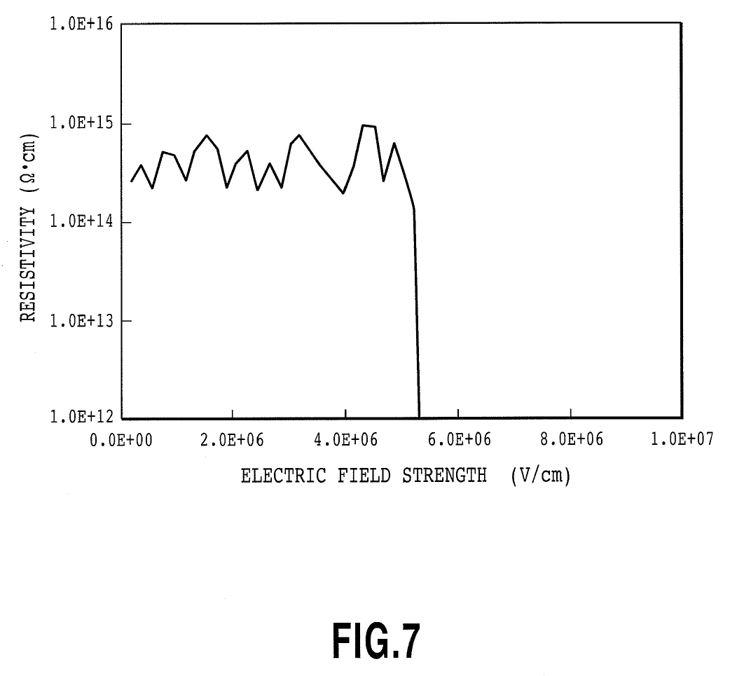

### EXPLANATION OF REFERENCE NUMERALS

10 substrate transfer jig
20 ultraviolet light lamp
30 temperature keeping device
40 coating film forming device
50 substrate pre-treatment device
60 coating film drying device
70 reaction gas introduction pipe
80 product gas exhaustion pipe
90 gas blocking curtain
100 substrate

### BEST MODES FOR CARRYING OUT THE INVENTION

An insulating layer comprising a semiconductor device fabricated according to the present invention is formed of a silicon oxide thin film fabricated by a coating process. The silicon oxide thin film is obtained through a conversion reaction from a coat film of a silicon compound including a silazane structure or a siloxane structure. The silazane structure herein (the following [Chemical formula 1]) and the siloxane structure herein (the following [Chemical formula 2]) represent the chemical structures represented by the following chemical formulas, respectively:

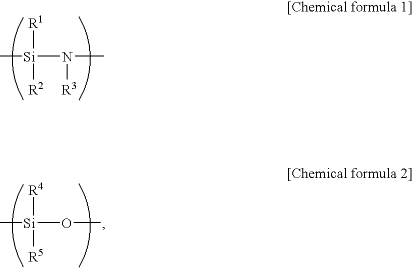

where R¹, R², R³, R⁴, and R⁵ each independently represent a substituent selected from the group consisting of a hydrogen atom, an alkyl group, an alkenyl group, an alkoxy group, a hydroxyalkyl group, a carboxyalkyl group, an alkylcarbonyl group, an alkoxycarbonyl group, an alkylcarbonyloxy group, an aromatic hydrocarbon group and an aromatic heterocyclic group.

The molecular chain of the above compound may have any of a linear shape, a cyclic shape and a cross-linked network shape. The molecular weight and the molecular-weight distribution of the above compound are not particularly specified; however, a compound having a molecular weight of 100 to 100000 is commonly used.

With an apparatus for forming a thin film device of the present invention, a substrate coated with the silicon compound is irradiated with ultraviolet light in a controlled atmosphere of gas while maintained at a specific temperature of 200° C. or below. Thereby, the silicon compound thin film is converted into a silicon oxide thin film, and simultaneously improvement of physical and electrical performances is achieved by a thermal annealing effect. Accordingly, a thin film having properties controlled according to its application in use can be easily fabricated.

With the present invention, a silicon oxide thin film having high insulating performance can be obtained by only irradiating a coating film of the silicon compound with ultraviolet rays with its temperature maintained at 200° C. or less. Thus, the heating temperature may be by far lower than the heating temperatures of 400° C. to 1000° C. or more at which the heating treatment of the conventional sol-gel method or thermal decomposition method is performed. Accordingly, thin films with a large-area can be manufactured in a shorter period and at a lower energy cost than those manufactured by these methods, and can be produced without requiring large-scale equipment, such as equipment for heat insulation. As a result, the cost of a manufacturing apparatus and the manufacturing cost of the films are greatly reduced. Meanwhile, the vacuum process such as vapor deposition or sputtering has conventionally been the only option for forming a silicon oxide thin film on a plastic substrate with low heat-resistance, which necessitates a special film-formation chamber and a high performance evacuation device. In contrast, the present invention makes it possible to fabricate a high-performance silicon oxide thin film device on a plastic substrate with a simple apparatus.

Particularly, the present invention makes it possible to form a high-performance electronic device, such as a thin film transistor, on a sheet substrate made of plastics which is light, plastic and highly-formable. Plastic sheet substrates commonly used so far has heat resistant temperatures of at most approximately 200° C. The present invention makes it possible to form a plastic sheet device with a thin film having necessary electric characteristics by a process at 200° C. or below, and thus is expected to be applied to low-weight flexible devices which will be produced in future.

The silicon oxide thin film fabricated according to the present invention is obtained by applying the compound on a substrate to thereby fabricate a precursor thin film, and by subjecting the precursor thin film to the conversion reaction. The substrate used herein is not particularly limited, and any substrate may be used. In general, substrates suitably used are flexible substrates of plastics such as polycarbonate, polyether imide, polyimide, polyethylene terephthalate (PET), polyethylene naphthalate, polypropylene, polyphenylene sulfide, polyether ether ketone, polyether ketone, polyether sulfone, polysulfone, polyphenylene sulfide, polyarylate and polyaramide; however, a glass, metal or ceramic substrate or the like may be used. Alternatively, a crystalline substrate of silicon, galliumnitride, galliumarsenide, galliumphosphide and the like, can be used. In such case, in order to stabilize the device, to lengthen the life thereof, and to improve processability of a sealing thin film formed on the substrate, the substrate may be maded by mixing or stacking multiple materials or subjected to a surface treatment.

An apparatus for forming a thin film of the present invention includes means for performing cleaning, degassing, impurity-removal or the like of the surface of the substrate on which the silicon oxide thin film is fabricated, in order to improve the physical and electrical performances of the thin film and to improve the adhesion of the coating film. The methods related to the means are not particularly limited. Cleaning and impurity-removal methods commonly used include: soak cleaning, flow-liquid cleaning, ultrasonic cleaning by using clean water, an organic chemical liquid, an acidic chemical liquid, an alkaline chemical liquid, or a mixture liquid thereof; cleaning by contact with vapor produced from the above-mentioned chemical liquid; cleaning by contact with ozone or a reactive gas species (such as a molecule, ion, radical or plasma gas); an impurity-removing method in which an inert chemical species such as argon or xenon is collided with the surface of the substrate; an impurity-removing method in which the substrate is irradiated with laser or any of the various energy rays; and the like. Meanwhile, degassing methods commonly used include: a heating treatment; irradiation with laser or any of the various energy rays; electricity-discharging treatment; and the like.

In order to control surface properties, such as wettability, of the surface of the substrate, the surface of an electrode fabricated on the substrate, or the like, a surface modification layer is formed by applying a surface active compound or the like to the surface or by making a surface active compound or the like adsorbed thereinto, before the silicon compound is applied to the substrate. Thereafter, the silicon compound is applied to the surface modification layer to build a multi-layer structure, which leads to improvement in adhesion, denseness, surface smoothness and the like of the thin film device. Hence, a thin film device having excellent mechanical and electrical performance can be obtained.

The silicon oxide thin film fabricated by using the apparatus for forming a thin film is obtained by fabricating a precursor thin film in the step of applying the above mentioned silicon compound to a substrate, and by subjecting the precursor thin film to the conversion reaction. Here, the method for forming the coating film is not particularly limited, and commonly used methods may include: a spin coating method, a dip coating method, a cast coating method, a spray coating method, an inkjet method, and a transfer method; and common printing methods which evolve therefrom, such as letterpress, screen printing, offset printing, and gravure printing; a soft lithography printing method, such as microcontact printing, micromolding; and the like.

The thin film formed of the silicon compound having the silazane structure or the siloxane structure used in the present invention is formed by the coating method. As for solvents used in this step, an aromatic hydrocarbon, an aliphatic hydrocarbon, an alicyclic hydrocarbon, a halogenated hydrocarbon, a halogenated aromatic hydrocarbon, ethers, amines and the like can be used. Examples of commonly suitably used solvents include benzene, toluene, xylene, ethylbenzene, cyclohexane, methylcyclohexane, pentane, hexane, heptane, octane, nonane, decane, ethyl ether, dipropyl ether, dibutyl ether, methyl ethyl ketone, methyl isobutyl ketone, tetrahydrofuran, chloroform, methyl chloride, pyridine and the like. These solvents are preferably purified by thoroughly removing impurities such as water and trace amounts of inorganic components or the like.

The thin film formed of the silicon compound having the silazane structure or the siloxane structure used in the present invention is formed by an application method. As for the solvent used in this step, a single component solvent or a mixture solvent containing two or more of the above-described solvents is used. Particularly, when a drying process of the coating film is controlled by using a mixture solvent containing two or more solvents with different physical properties such as boiling point and dissolving ability of a silicon compound, the obtained thin film can be provided with high thin film qualities such as high uniformity and zero defect.

The thin film formed of the silicon compound having the silazane structure or the siloxane structure used in the present invention is applied in each operation in a thickness of preferably 5 nm to 10 μm, both inclusive, and preferably 50 nm to 2 μm, both inclusive.

In the present invention, two or more coating steps of the silicon compound thin film can be performed to fabricate a thin film having a desired sufficient film thickness. Here, the above-mentioned cleaning or degassing step can be also performed before and after each of the coating steps. Meanwhile, when the above-mentioned two or more coating steps are performed, the thin film can be provided by stacking thin films of different compounds.

For the silicon compound thin film used in the present invention, a step may be provided in which, after the thin film is applied and formed, the film is heated to partially or completely remove the solvent. A warming device used here is not particularly limited; however, a resistance heating device, an infrared heat device or the like is commonly used. Here, the atmospheric temperature in the heating or the like varies depending on the solvent used; however, the preferable warming temperature is generally 20° C. to 150° C., both inclusive.

Alternatively, a method can be employed in which the coating film is irradiated with laser or any of the various energy rays to remove the solvent. The atmosphere in which the silicon compound thin film is placed when warmed is preferably under the barometric pressure atmosphere. Here, the time required to remove the solvent by heating is not particularly limited. The time is commonly 1 second to 180 minutes, both inclusive, and preferably 30 seconds to 60 minutes.

Next, the substrate having a silicon compound thin film is transferred to a reaction section to be irradiated with ultraviolet light while kept at a certain temperature in a controlled atmosphere of gas. In this case, means for transfer is not particularly limited. The substrate can be transferred within a reaction chamber at a certain constant speed in order to continuously fabricate the thin film device. However, some of the silicon compounds used for the present invention may degrade because of oxygen or moisture in the atmosphere or depending on the temperature. The atmosphere in which the substrate with the silicon compound thin film attached thereto is transferred is therefore preferably controllable.

In the present invention, the atmosphere of gas and the temperature of the reaction section for converting the silicon compound coating film into silicon oxide with ultraviolet light irradiation are preferably controllable to appropriate conditions.

During the step of converting the silicon compound thin film used in the present invention into a silicon oxide thin film, ozone, reactive oxygen molecules, or reactive oxygen atoms, which are more reactive than air and oxygen gas, are preferably used as part or all of the components of the atmospheric gas. The reactive oxygen spices used here can be obtained by a commonly-used ozone generating device or by irradiating, with ultraviolet rays, an atmosphere containing oxygen, ozone, carbon dioxide, carbonmonoxide, sulfur dioxide, sulfur suboxide, water vapor, oxygen nitride, nitrogen dioxide, nitrous oxide, oxygen subnitride, reactive oxygen molecules, atoms, radicals or the like.

Nitrogen, argon, ammonia and hydrogen, which contain no oxygen atom may be used as part of the atmospheric gas during the step of converting the silicon compound thin film used in the present invention into a silicon oxide thin film. Of these, nitrogen and argon are inert gases, which do not contribute to the conversion reaction into silicon oxide. Addition of these gasses allows adjustments of the reaction gas concentration in the atmospheric gas and the ultraviolet light irradiation intensity from an ultraviolet light lamp, and thereby the film formability and the reaction rate of the silicon oxide film can be controlled. Meanwhile, ammonia and hydrogen function as catalysts for the conversion reaction, thereby making it possible to obtain the effects of reaction acceleration, film quality improvement and the like.

The atmospheric gas containing the oxygen chemical species is irradiated with the ultraviolet light to convert the silicon compound thin film used in the present invention into the silicon oxide thin film. Instead, the silicon oxide can also be obtained through the following reaction mechanism. Specifically, the silicon compound thin film is directly irradiated with the above-described energy rays to break chemical bonds of the silicon compound in the thin film. Then, the oxygen chemical species in the atmosphere are directly taken into the film. Accordingly, the conversion reaction to the silicon oxide is accelerated.

In the irradiation of ultraviolet light in an atmosphere containing the oxygen chemical species for converting the silicon compound thin film used in the present invention into the silicon oxide thin film, the wavelength of the irradiated ultraviolet light is not particularly limited, and the wavelength commonly used is 100 nm to 450 nm. Light with such a wavelength can be obtained by a deuterium lamp, a xenon lamp, a metal halide lamp, an excimer lamp, a mercury lamp, or the like as well as an excimer laser or the like.

In the irradiation of ultraviolet light in an atmosphere containing the oxygen chemical species for converting the silicon compound thin film used in the present invention into the silicon oxide thin film, the higher the irradiation energies of the irradiated ultraviolet light per unit time and unit area are, the more the conversion efficiency into the silicon oxide is improved. However, the same effect can be obtained by a prolonged irradiation of ultraviolet light with small energy. Accordingly, the necessary minimum irradiation energies of the irradiated ultraviolet light per unit time and unit area are not particularly specified. Moreover, continuous irradiation of ultraviolet light rays does not necessarily have to be performed, and intermittent light irradiation or light irradiation with a pulse light source may be employed.

In the present invention, the silicon compound having the silazane structure or the siloxane structure is used as a raw material, and applied to a substrate to form a raw thin film. Then, the raw film is converted to form a silicon oxide thin film. In the conversion of the silicon compound thin film into the silicon oxide thin film, the processing temperature is commonly 0° C. to 200° C., both inclusive. However, the higher the temperature is, the more excellent electrical property the obtained silicon oxide thin film has, provided that the temperature is less than the heat resistant temperature of the substrate. In addition, the time required for the conversion reaction is not particularly limited, and the time is generally 1 minute to 720 minutes, both inclusive, and preferably 5 minutes to 120 minutes.

In part or all of the processes for converting the silicon compound thin film used in the present invention into the silicon oxide thin film, it is preferable to perform a heating treatment at 0° C. to 200° C., both inclusive, in a reaction atmosphere containing ozone, water vapor, reactive oxygen molecules, reactive oxygen atoms or the like which are more reactive than ordinal oxygen gas. Here, the heating treatment on the thin film of the coating raw material may be performed simultaneously with the irradiation of ultraviolet light. Alternatively, the heating treatment may be separately performed after a certain-period irradiation of energy rays.

In the manufacturing step of converting the silicon compound thin film used in the present invention into the silicon oxide thin film, the manner with which the heating treatment is performed at 0° C. to 200° C., both inclusive, in an reaction atmosphere containing ozone, water vapor, reactive oxygen molecules, reactive oxygen atoms or the like is not particularly limited; however, a resistance heating manner, a lamp heating manner, a laser heating manner, an electromagnetic heating manner or the like is commonly employed. In addition, the form, performance and arrangement of the heating device used in the heating treatment are not particularly limited, as long as the heating device can directly or indirectly control the temperature of the surface of the thin film or the inside of the film.

The conversion reaction for converting the silicon compound thin film used in the present invention into the silicon oxide thin film is performed at least once to thereby obtain the silicon oxide thin film that is finally needed. Here, the thickness of the film is not particularly limited.

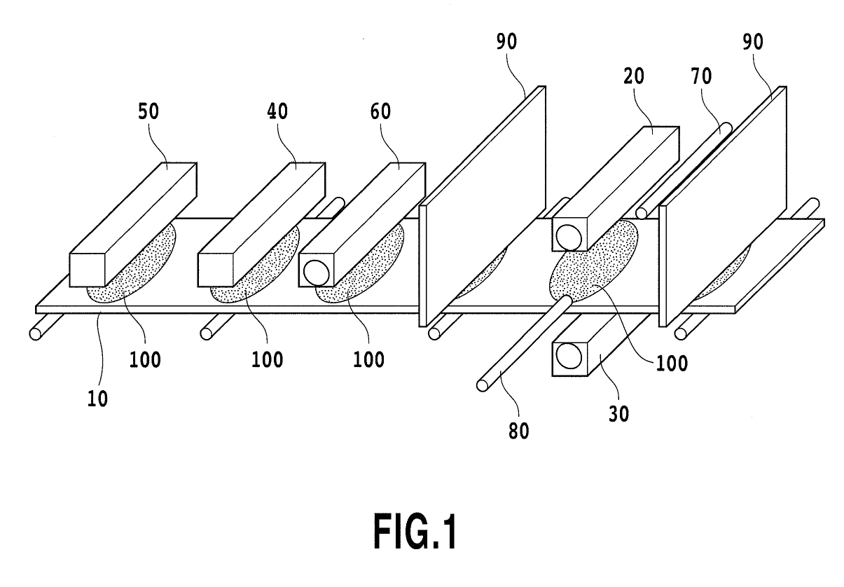

FIG. 1 shows a conceptual view of the apparatus for forming a thin film of the present invention. This apparatus for forming a thin film is used, for example, to form silicon oxide thin films used as a sealing layer and an insulating layer of a thin film transistor device in a process for manufacturing a display device on a flexible plastic substrate. FIG. 1 shows the concept of sections and a mechanism for sequentially moving the substrate from one section to another during the transfer of the substrate in the production apparatus by using a substrate transfer device. Specifically, the sections include: a pre-treatment section for performing a surface treatment to conduct cleaning or degassing of the substrate surface or to improve the wettability of the substrate surface; a coating section for forming a thin film by applying the silicon compound on the substrate; a drying section for partially or completely drying and removing the solvent in the coat film; and a reaction section defined by gas shielding curtains. FIG. 1 also shows the concept of arrangement of these devices. The pre-treatment section includes a substrate pre-treatment device 50 having the above-mentioned substrate cleaning means and substrate surface modifying means. The coating section includes a coating film forming device 40 having means for coating the substrate with a liquid containing the above-mentioned silicon compound as its partial component or entire component. The drying section includes a drying device 60 for completely or partially drying the coating film by heat application or pressure reduction. The reaction section includes a gas introduction pipe 60 and a gas exhaustion pipe 70 for introducing a controlled atmospheric gas. The reaction section further includes an ultraviolet light lamp 20 and a temperature keeping device 30. The ultraviolet light lamp 20 has means for applying ultraviolet light rays, from right above the coated surface, to the coating film on the substrate transferred through the gas shielding curtain 80 which prevents outflow of the atmospheric gas to the outside of the reaction section. The temperature keeping device 30 has means for heating and keeping the substrate and the thin film on the substrate at a certain temperature. In some cases such as a case where the temperature of the machinery and materials is raised to the heat resistant temperature or more by the light irradiation, the temperature keeping device 30 has means for cooling the substrate. Furthermore, although not shown, means for measuring a substrate temperature, means for evacuating the reaction section, means for controlling the composition, the flow rate, the pressure, and the like of the gas introduced to the reaction section or the like are provided.

The above-mentioned apparatus for manufacturing a thin film device does not necessarily include the drying section for drying the solvent and thereby removing the solvent from the coat film. The ultraviolet light radiation or the heating by the temperature keeping device in the reaction section can also be utilized for the removal of the solvent.

In the above-mentioned apparatus for manufacturing a thin film device, the pre-treatment section, the coating section, the drying section and the reaction section are not necessarily included in a single apparatus, and each can be formed as an independent device, depending on the specifications of the substrate or the thin film device.

The material and the shape of a jig 10 for transferring the substrate is not particularly limited. The jig commonly used is made of soft rubber, metal, or glass, and may have a shape of a grid or a rod in addition to a sheet shown in FIG. 1.

The speed of transferring the substrate for each of the steps may be required to vary, which requires means for independently controlling the transferring speed for each of the steps. As means for absorbing the speed differences among the steps which may be caused by this control, a multi-stage roll mechanism or a dancer roll mechanism is used depending on the situation.

### Example 1

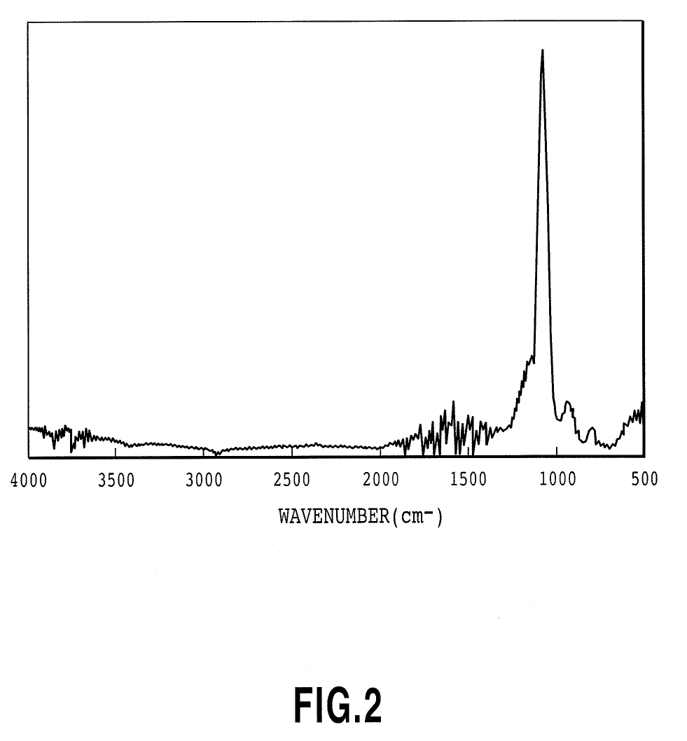

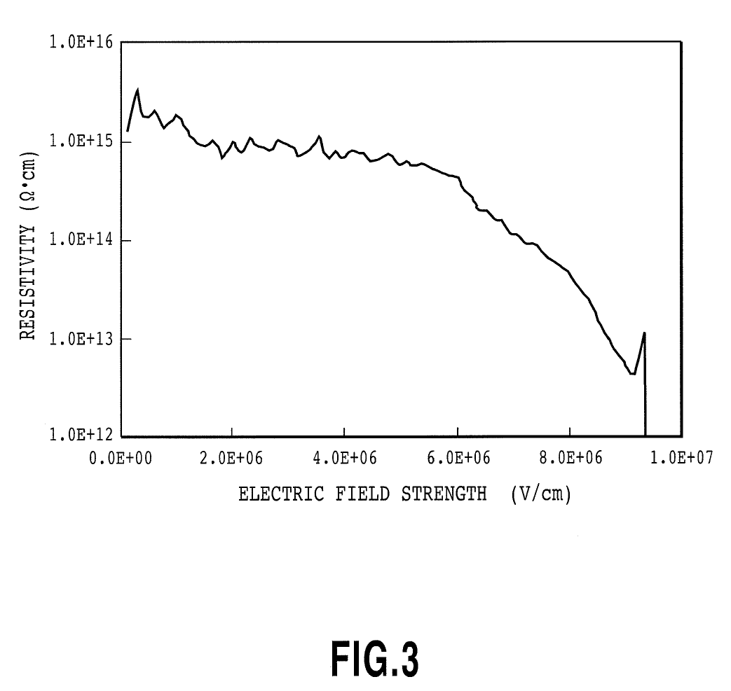

Poly(perhydrosilazane) was dissolved in a mixture solvent of dibutyl ether and cyclohexanone (mixture ratio: 2:5) to fabricate a solution at a concentration of approximately 6.7 wt %, which was used as a raw material solution for fabricating a thin coating film. A mirror-polished silicon wafer of 2 cm in diameter and 1 mm in thickness was used as a substrate on which a silicon oxide thin film was eventually fabricated. A surface cleaning by the method shown below was performed as a pre-treatment of the substrate. The substrate was flushed with ultrapure water for one minute to thereby remove substances attached to the surface. Thereafter, the water was removed by an air gun. Subsequently, the substrate was transferred into a plasma dry cleaner PDC 510 manufactured by Yamato Scientific Co., Ltd., and was subjected to an oxygen plasma treatment by a DP method for 3 minutes. The substrate was then immersed for 2 minutes in a hydrofluoric acid obtained through 100-fold dilution with ultrapure water, and thereafter subjected to sufficient running water cleaning by use of ultrapure water. The substrate thus pre-treated was introduced into the coating section, and mounted on a spin coater. Thereafter, approximately 1 cc of the raw material liquid was spread on the substrate by using a Teflon (registered trademark) syringe fitted with a disposable filter (pore diameter: 0.45 microns) made of Teflon (registered trademark). Thereafter, the substrate was rotated at a rate of 5000 rpm for 60 seconds to thereby obtain a coating film of poly (perhydrosilazane) with an even thickness. After the completion of the rotation, the substrate was heated at 50° C. for 15 minutes to thereby partially remove the solvent. Immediately thereafter, the substrate was introduced into the reaction section. To control the gas atmosphere in the reaction section, a 4:1 mixture gas of nitrogen and oxygen, which had passed through a desiccant, was introduced through a gas inlet. Here, the gas flow rate was 100 sccl per minute. Both the stage and the substrate in close contact therewith were heated, from the back of the stage on which the substrate was set, by using an infrared ray lamp heating device. The temperature of the stage was kept at 200° C. by using a thermocouple thermometer fitted on the stage. Simultaneously, ultraviolet light was applied on the substrate from thereabove by using an ultraviolet light lamp (Xe2 excimer lamp). The reaction time employed was 180 minutes. After the reaction, the substrate was taken out, and thus a thin film device was obtained. The silicon oxide thin film thus fabricated had a thickness of approximately 105 nm. FIG. 2 shows an FT-IR pattern spectrum of the thin film thus fabricated. In the spectrum, all absorption peaks seen in the spectrum of the thin film of the raw material disappeared, and only the absorption at 1100 cm⁻¹ attributable to the bond between silicon and oxygen is strongly seen. Accordingly, it is seen that the poly (perhydrosilazane) thin film which is the raw material was completely converted into a silicon oxide thin film. FIG. 3 shows a correlation curve between the resistivity and the electric field strength of the silicon oxide thin film. The withstand voltage of the thin film was approximately 6 MV/cm², and the resistivity of the thin film was 10¹⁵ Ωcm.

### Example 2

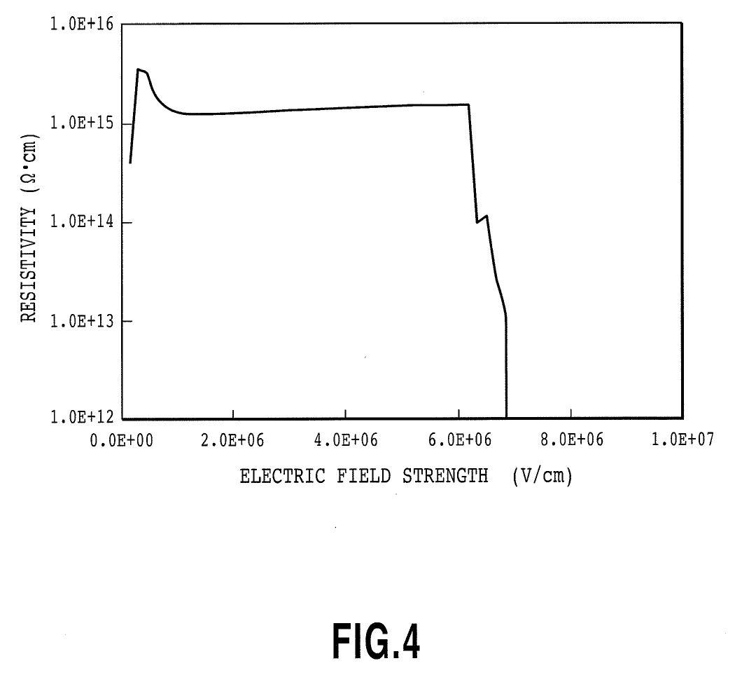

Poly (perhydrosilazane) was dissolved in a mixture solvent of dibutyl ether and cyclohexanone (mixture ratio: 2:5) to fabricate a solution at a concentration of approximately 6.7 wt o, which was used as a raw material solution for fabricating a thin coating film. A glass plate of 2 cm square with 1 mm thickness was used as a substrate on which a silicon oxide thin film was eventually fabricated. On a surface of the substrate, a chrome metal thin film had been fabricated by sputtering. A surface cleaning by the method shown below was performed as a pre-treatment on the substrate. The substrate was flushed with ultrapure water for one minute to thereby remove substances or the like attached to the surface. Thereafter, the water was removed by an air gun. Subsequently, the substrate was transferred into a plasma dry cleaner PDC 510 manufactured by Yamato Scientific Co., Ltd., and was subjected to an oxygen plasma treatment by a DP method for 3 minutes. The substrate was then immersed for 2 minutes in a hydrofluoric acid obtained through 100-fold dilution with ultrapure water, and thereafter subjected to sufficient running water cleaning by use of ultrapure water. The substrate thus pre-treated was introduced into the coating section, and mounted on a spin coater. Thereafter, approximately 1 cc of the raw material liquid was spread on the substrate by using a Teflon (registered trademark) syringe fitted with a disposable filter (pore diameter: 0.2 microns) made of Teflon (registered trademark). Thereafter, the substrate was rotated at a rate of 5000 rpm for 60 seconds to thereby obtain a coating film of poly (perhydrosilazane) with an even thickness. After the completion of the rotation, the substrate was heated at 50° C. for 10 minutes to thereby partially remove the solvent. Immediately thereafter, the substrate was introduced into the reaction section. To control the gas atmosphere in the reaction section, a 4:1 mixture gas of nitrogen and oxygen, which had passed through a desiccant, was introduced through a gas inlet. Here, the gas flow rate was 100 sccl per minute. Both the stage and the substrate in close contact therewith were heated, from the back of the stage on which the substrate was set, by using an infrared ray lamp heating device. The temperature of the stage was kept at 200° C. by using a thermocouple thermometer provided on the stage. Simultaneously, ultraviolet light was applied on the substrate from thereabove by using an ultraviolet light lamp (Xe2 excimer lamp). The reaction time employed was 180 minutes. After the reaction, the substrate was taken out, and thus a thin film device was obtained. The silicon oxide thin film thus fabricated had a thickness of approximately 63 nm. FIG. 4 shows a correlation curve between the resistivity and the electric field strength of the silicon oxide thin film. The withstand voltage of the thin film was approximately 6 MV/cm², and the resistivity of the thin film was 10¹⁵ Ωm.

### Example 3

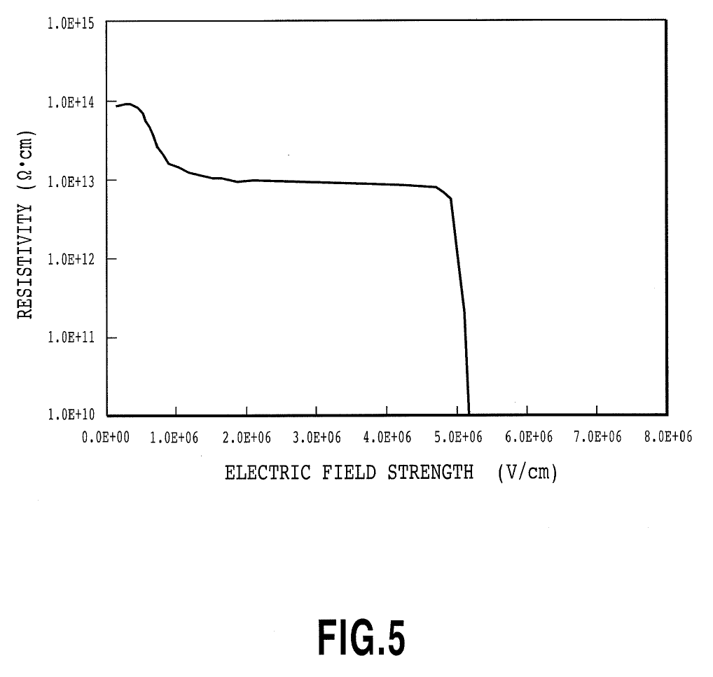

Poly(perhydrosilazane) was dissolved in a mixture solvent of dibutyl ether and cyclohexanone (mixture ratio: 1:5) to fabricate a solution at a concentration of approximately 4.0 wt %, which was used as a raw material solution for fabricating a thin coating film. A glass plate of 2 cm square with 1 mm thickness was used as a substrate on which a silicon oxide thin film was eventually fabricated. On a surface of the substrate, a chrome metal thin film had been fabricated by sputtering. A surface cleaning by the method shown below was performed as a pre-treatment on the substrate. The substrate was passed into a Teflon (registered trademark) container containing a liquid crystal substrate cleaning liquid Semico Clean 23 manufactured by Furuuchi Chemical Corporation in an undiluted form, and then subjected to ultrasonic cleaning for 15 minutes. Thereafter, the substrate was passed into a Teflon (registered trademark) container containing ultrapure water, and then subjected to ultrasonic cleaning for 30 minutes. After that, the substrate was subjected to running water cleaning using ultrapure water, and then water attached to the substrate was removed by using an air gun. Next, a hexamethyldisilazane thin film was fabricated on a surface of the substrate as a surface modification layer. The fabrication procedure was as follows. Into a sealable Teflon (registered trademark) container, 1 ml of hexamethyldisilazane and 3 ml of chloroform was charged. Thereafter, a pedestal was introduced into the container, and the pre-treated substrate was placed on the pedestal while avoided from being in contact with the liquid. The container was sealed, and left at rest for 30 minutes while the entire container was kept at 50° C. Thereafter, the substrate was taken out from the container and then subjected to cleaning using chloroform. Thus, a thin film of hexamethyldisilazane was fabricated on the surface with Cr. Immediately thereafter, the substrate was introduced into the coating section, and mounted on a spin coater. Thereafter, approximately 1 cc of the raw material liquid was spread on the substrate by using a Teflon (registered trademark) syringe provided with a disposable filter (pore diameter: 0.45 microns) made of Teflon (registered trademark). Thereafter, the substrate was rotated at a rate of 5000 rpm for 60 seconds to thereby obtain a coating film of poly (perhydrosilazane) with even thickness. After the completion of the rotation, the substrate was heated at 50° C. for 15 minutes to thereby partially remove the solvent. Immediately thereafter, the substrate was introduced into the reaction section. To control the gas atmosphere in the reaction section, a dry air was introduced through a gas inlet. Here, the pressure of compression air was 0.252 MPa, and the flow rate thereof was 3.0 liters per minute. Thereafter, ultraviolet light irradiation was performed for 180 minutes by using a Xe2 excimer lamp placed 3 mm away from the surface on which the thin film was applied, with a center wavelength of 172 nm and an output of 24 milliwatt per square centimeter. The temperature inside the reaction container was kept at 22° C. After the irradiation was completed, oxygen gas containing ozone was introduced into the reaction section in order to control the gas atmosphere around the substrate. The ozone concentration in the oxygen gas was set to 75 to 85 g/Nm³, and the gas flow rate was 1 litter per minute. The temperature inside reaction section was kept at 200° C. Heating treatment was performed for 5 hours in that state. Thereafter, the substrate was taken out, and thus a thin film device was obtained. The silicon oxide thin film thus fabricated had a thickness of approximately 55 nm. FIG. 5 shows a correlation curve between the resistivity and the electric field strength of the silicon oxide thin film. The withstand voltage of the thin film was approximately 5 MV/cm², and the resistivity of the thin film was 10¹³ Ωcm.

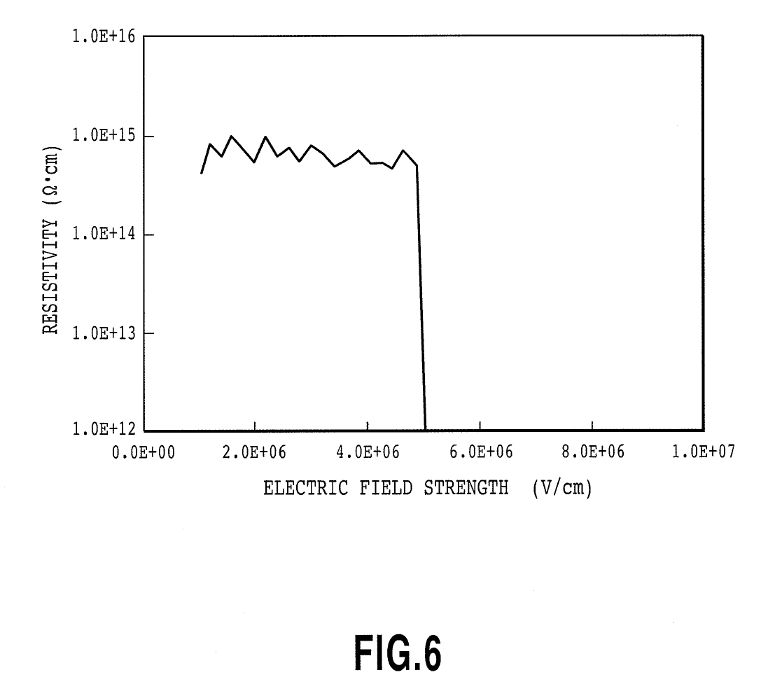

(Reference Example 1) Poly (perhydrosilazane) was dissolved in dibutyl ether at a concentration of approximately 6.7 wt % to fabricate a raw material solution for fabricating a thin coating film. A mirror-polished silicon wafer of 2 inches in diameter was used as a substrate on which a silicon oxide thin film was eventually fabricated. A surface cleaning by the method shown below was performed as a pre-treatment on the substrate. The substrate was passed into a Teflon (registered trademark) container containing a liquid crystal substrate cleaning liquid Semico Clean 23 manufactured by Furuuchi Chemical Corporation in an undiluted form, and then subjected to ultrasonic cleaning for 15 minutes. Thereafter, the substrate was passed into a Teflon (registered trademark) container containing ultrapure water, and then subjected to ultrasonic cleaning for 30 minutes. After that, the substrate was subjected to running water cleaning using ultrapure water, and then water attached to the substrate was removed by using an air gun. The substrate was then immersed for 1 minute in a hydrofluoric acid obtained through 100-fold dilution with ultrapure water, and thereafter subjected to sufficient cleaning by use of ultrapure water. The substrate thus subjected the cleaning was transferred to the coating section, and mounted on a spin coater. Thereafter, approximately 1 cc of the raw material liquid was spread on the substrate by using a Teflon (registered trademark) syringe provided with a disposable filter (pore diameter: 0.2 microns) made of Teflon (registered trademark). Thereafter, the substrate was rotated at a rate of 5000 rpm for 60 seconds to thereby obtain a coating film of poly (perhydrosilazane) with even thickness. After the completion of the rotation, the substrate was heated for 10 minutes by being left at rest on a hot plate heated at 50° C. to thereby partially remove the solvent remaining in the film. Immediately thereafter, the substrate was introduced into the reaction section. The gas atmosphere in the reaction section was in a state where dry air was always flowing. Here, the pressure of compression air was 0.246 MPa, and the flow rate thereof was 3.0 liters per minute. Thereafter, ultraviolet light irradiation was performed for 180 minutes by using a Xe2 excimer lamp placed 3 mm away from the surface on which the thin film was applied, with a center wavelength of 172 nm and an output of 24 milliwatts per square centimeter. The temperature inside the reaction container was kept constant at 28° C. After the ultraviolet light irradiation was completed, oxygen gas containing ozone was introduced into the reaction section. The ozone concentration in the mixed gas was set to 75 to 85 g/Nm³. The substrate and the gas therearound were heated by a resistance heating device, and kept constant at 200° C. by using a temperature controller. Heating treatment was performed for 300 minutes in that state. The substrate was taken out, and thus a thin film device was obtained. The obtained silicon oxide thin film had a thickness of approximately 35 nm. FIG. 6 shows a correlation curve between the resistivity and the electric field strength of the silicon oxide thin film. The withstand voltage of the thin film was approximately 5 MV/cm², and the resistivity of the thin film was 10¹⁵ Ωcm. In addition, the surface roughness of the thin film surface was approximately 0.16 nm, in terms of RMS value.

(Reference Example 2) Poly (perhydrosilazane) was dissolved in dibutyl ether at a concentration of approximately 6.7 wt % to fabricate a raw material solution for fabricating a thin coating film. A mirror-polished silicon wafer of 2 inches in diameter was used as a substrate on which a silicon oxide thin film was eventually fabricated. A surface cleaning by the method shown below was performed as a pre-treatment on the substrate. The substrate was passed into a Teflon (registered trademark) container containing a liquid crystal substrate cleaning liquid Semico Clean 23 manufactured by Furuuchi Chemical Corporation in an undiluted form, and then subjected to ultrasonic cleaning for 15 minutes. Thereafter, the substrate was passed into a Teflon (registered trademark) container containing ultrapure water, and then subjected to ultrasonic cleaning for 30 minutes. After that, the substrate was subjected to running water cleaning using ultrapure water, and then water attached to the substrate was removed by using an air gun. The substrate was then immersed for 1 minute in a hydrofluoric acid obtained through 100-fold dilution with ultrapure, and thereafter subjected to sufficient cleaning by use of ultrapure water.

The substrate thus cleaned was transferred to the coating section, and mounted on a spin coater. Thereafter, approximately 1 cc of the raw material liquid was spread on the substrate by using a Teflon (registered trademark) syringe provided with a disposable filter (pore diameter: 0.2 microns) made of Teflon (registered trademark). Thereafter, the substrate was rotated at a rate of 5000 rpm for 60 seconds to thereby obtain a coating film of poly (perhydrosilazane) with even thickness. After the completion of the rotation, the substrate was heated for 10 minutes by being left at rest on a hot plate heated at 50° C. Immediately thereafter, the substrate was introduced into the reaction section. To control the gas atmosphere in the reaction section, an oxygen gas with a purity of 99.9% was always allowed to flow through a gas inlet. Here, the pressure of oxygen gas was 0.246 MPa, and the flow rate thereof was 1.0 litter per minute. Thereafter, ultraviolet light beams with wavelengths of 185 nm and 254 nm were irradiated for 180 minutes by using a low pressure mercury lamp placed 70 mm away from the surface on which the thin film was applied. The temperature inside the reaction section was kept constant at 27° C. After the reaction, oxygen gas containing ozone was introduced into the reaction section, while the substrate with the thin film fabricated thereon was placed thereinside. The gas flow rate was 1.0 litter per minute and the total pressure of the gas was 0.1 MPa. The ozone concentration in the oxygen gas was set to 75 to 85 g/Nm³. The temperature inside reaction section was heated by a resistance heating device, and kept constant at 200° C. by using a temperature controller. Heating treatment was performed for 300 minutes in that state. Thereafter, the substrate was taken out, and thus a thin film device was obtained. The fabricated silicon oxide thin film had a thickness of 54 nm. FIG. 4 shows a correlation curve between the resistivity and the electric field strength of the silicon oxide thin film. The withstand voltage of the thin film was approximately 5 MV/cm², and the resistivity of the thin film was 10¹⁴ Ωcm. In addition, the surface roughness of the thin film surface was approximately 0.20 nm, in terms of RMS value.

### INDUSTRIAL APPLICABILITY

The manufacturing method and the manufacturing apparatus according to the present invention allow a semiconductor device having an equivalent level of electrical properties, reliability, and durability to those used in the electronics industry to be fabricated on a plastic substrate with plasticity and a low heat-resistance through a coating process. This makes it possible to achieve a simple, energy-saving manufacturing process as well as to provide a film device, a large area device, and a flexible device. As a result, the manufacturing method and the manufacturing apparatus can be used in mass-producing electronic devices, such as electronic tag, electronic poster, and electronic paper, which require high level of impact resistance, weatherability, portability, low cost or the like.

1. An apparatus for forming a silicon oxide thin film, comprising:
coating means for coating a surface of a substrate with a coat film made of a silicon compound having a silazane structure or a siloxane structure;
control means for controlling an atmosphere of gas;
an ultraviolet light source provided above the coated surface; and
a substrate temperature keeping device provided below the substrate or a pedestal supporting the substrate.

2. The apparatus for forming a silicon oxide thin film according to claim 1, wherein the substrate temperature keeping device is a resistance heater or an infrared lamp heater.

3. The apparatus for forming a silicon oxide thin film according to claim 1, wherein the ultraviolet light source and the substrate temperature keeping device are arranged in parallel with each other on a plane perpendicular to a direction in which the substrate is transferred.

4. The apparatus for forming a silicon oxide thin film according to claim 1, wherein the gas includes one or a plurality of kinds selected from oxygen gas, hydrogen gas, nitrogen gas, ozone gas, ammonia gas, carbon monoxide gas, carbon dioxide gas, hydrogen peroxide gas, nitrogen monoxide gas, nitrogen dioxide gas, oxygen subnitride gas, and argon gas.

5. The apparatus for forming a silicon oxide thin film according to claim 1, further comprising coating means for forming a coat film on a substrate, the coating means including an entrance and an exit for the substrate to be transferred continuously between the ultraviolet light source and the substrate temperature keeping device.

6. The apparatus for forming a silicon oxide thin film according to claim 1, further comprising solvent removing means for partially or completely removing a solvent in the coat film except for a raw material.

7. The apparatus for forming a silicon oxide thin film according to claim 1, further comprising cleaning means provided at the previous stage of the coating means, for any of cleaning the substrate, degassing the substrate and removing impurities attached on the surface.

8. The apparatus for forming a silicon oxide thin film according to claim 1, further comprising a gas inlet and a gas outlet for generating a controlled atmosphere of gas.

9. The apparatus for forming a silicon oxide thin film according to claim 8, wherein the gas inlet and the gas outlet are oppositely arranged on the plane perpendicular to a direction in which the substrate is transferred.

10. The apparatus for forming a silicon oxide thin film according to claim 1, wherein curtain mechanisms are respectively provided at an entrance port and an exit port, for tools and materials, of a process chamber in which a conversion reaction from the silicon compound having a silazane structure or a siloxane structure into a silicon oxide is performed.

11. A method for forming a silicon oxide thin film, comprising:
coating a surface of a substrate with a coat film made of a silicon compound having a silazane structure or a siloxane structure; and
irradiating the surface of the substrate with ultraviolet light in an atmosphere of gas, while keeping the substrate at a temperature of 0° C. to 200° C., both inclusive.

12. A laminated body, comprising:
a substrate; and
a surface modification layer applied to or adsorbed onto an electrode formed on the substrate or an oxide film generated on a surface of the electrode, wherein a silicon oxide film is stacked on the modification layer by the method for forming a silicon oxide thin film according to claim 11.
